(19) United States
(12) Patent Application Publication
(10) Pub. No.: US 2007/0194247 A1
(43) Pub. Date: Aug. 23, 2007

(54) Compact optical module for fluorescence excitation and detection

(75) Inventors: Taylor A. Reid, Carlsbad, CA (US); Roger H. Taylor, San Diego, CA (US)

Correspondence Address: PALMER & DODGE, LLP;KATHLEEN M. WILLIAMS, 111 HUNTINGTON AVENUE, BOSTON, MA, 02199, US

(73) Assignee: Stratagene California

(21) Appl. No.: 11/510,520

(22) Filed: Aug. 25, 2006

Related U.S. Application Data
(60) Provisional application No. 60/713,011, filed on Aug. 31, 2005.

(51) Int. Cl. G01J 1/58; G01T 1/10; H01L 31/14; H01J 40/14; F21V 9/16

(52) U.S. Cl. 250/458.1; 250/459.1; 250/578.1; 250/553

(57) ABSTRACT

A compact optical module for fluorescence excitation and detection and methods for using same are disclosed. An apparatus for detecting fluorescence includes a substrate base, a detector adjacent to the substrate base for determining the amount of fluorescence, an emission filter adjacent to the detector, a light source for emitting an excitation light, the light source engaging the emission filter, and a cover formed over the detector, the emission filter, and the light source.

### RELATED APPLICATIONS

This application claims the benefit of U.S. Provisional Application No. 60/713,011, filed on Aug. 31, 2005. The entire teachings of the above application are incorporated herein by reference.

### BACKGROUND

The embodiments disclosed herein relate to fluorescence excitation and detection, and more particularly to a compact optical module for fluorescence excitation and detection and methods for using same.

Techniques for thermal cycling of DNA samples are known in the art. By performing a polymerase chain reaction (PCR), DNA can be amplified. It is desirable to cycle a specially constituted liquid biological reaction mixture through a specific duration and range of temperatures in order to successfully amplify the DNA in the liquid reaction mixture. Thermocycling is the process of melting DNA, annealing short primers to the resulting single strands, and extending those primers to make new copies of double stranded DNA. The liquid reaction mixture is repeatedly put through this process of melting at high temperatures and annealing and extending at lower temperatures.

In a typical thermocycling apparatus, a biological reaction mixture including DNA will be provided in a large number of sample wells on a thermal block assembly. Quantitative PCR (qPCR) uses fluorogenic probes to sense DNA. Instrumentation designed for qPCR must be able to detect approximately 1 nM of these probes in small volume samples (e.g., approximately 25 μl). The detection method must be compatible with the thermal cycling required for qPCR. It is desirable that the detection method also be capable of distinguishing multiple fluorogenic probes in the same sample.

Enhancing the sensitivity of fluorescence detection of a qPCR instrument or method improves the usefulness of that instrument or method by enabling detection of DNA sooner, that is, after fewer thermal cycles.

Prior art systems use the same light path for excitation and detection. In those systems excitation light is directed to a beam splitter, which transmits typically about one-half of the excitation light to the sample. Some of the emitted light from the sample comes back to the beam splitter and a portion of that light, typically about one-half, is directed to a detector. By using beam splitters, only about one-half of the light is reflected and transmitted; therefore, only about one-quarter of the signal is measured. Using beam splitters also increases the size and complexity of the system and may cause the detector to be further away from the samples.

U.S. Pat. No. 5,757,014 to Bruno et al. discloses an optical detection device for analytical measurements of chemical substances. The Bruno et al. device includes an excitation light guide and an emission light guide that share the same optical light path. U.S. Pat. No. 6,563,581 to Oldham et al. discloses a system for detecting fluorescence emitted from a plurality of samples in a sample tray. The Oldham et al. device includes a plurality of lenses, an actuator, a light source, a light direction mechanism and an optical detection system. U.S. Pat. No. 6,015,674 to Woudenberg et al. discloses a system for measuring in real time polynucleotide products from nucleic acid amplification processes, such as polymerase chain reaction (PCR). The Woudenberg et al. device includes a sample holder, an optical interface, a lens, and a fiber optic cable for delivering an excitation beam to a sample and for receiving light emitted by the sample.

Other prior art methods use fiber optics to deliver the excitation light to and collect the fluorescence from the sample. These methods may either use independent fiber optics for each sample or scan the same fiber optics over all the samples. Some methods illuminate the entire collection of samples simultaneously and detect the fluorescence with large area detectors.

### SUMMARY OF THE INVENTION

A compact optical module for fluorescence excitation and detection and methods for using same are disclosed.

According to aspects illustrated herein, there is provided an apparatus for detecting fluorescence including a substrate base, a detector adjacent to the substrate base for determining the amount of fluorescence; an emission filter adjacent to the detector, a light source for emitting an excitation light, the light source engaging the emission filter, and a cover formed over the detector, the emission filter, and the light source.

According to aspects illustrated herein, there is provided a detection system for detecting fluorescence from a plurality of samples including a detection aperture for receiving fluorescent light, a plurality of light emitting diodes for emitting an excitation light, the plurality of light emitting diodes located around the detection aperture, and a detector adjacent to the detection aperture for determining the amount of fluorescence.

According to aspects illustrated herein, there is provided a method for detecting fluorescence including emitting an excitation light from a plurality of light sources located around a detection aperture, directing the excitation light to an excitation filter, illuminating a sample with the excitation light to generate an emission light, and detecting the optical characteristics of the emission light using a detector located at the end of the detection aperture.

### BRIEF DESCRIPTION OF THE DRAWINGS

The presently disclosed embodiments will be further explained with reference to the attached drawings, wherein like structures are referred to by like numerals throughout the several views. The drawings are not necessarily to scale, the emphasis having instead been generally placed upon illustrating the principles of the presently disclosed embodiments.

FIG. 1 is a bottom perspective view of a compact optical module over a sample tube.

FIG. 2 is a top perspective view of a compact optical module.

FIG. 3 is a sectional perspective view of a compact optical module taken along line A-A in FIG. 2.

FIG. 4 is a perspective view of a compact optical module mounted to an assembly that shows the path as the optical module is scanned over a plurality of sample tubes.

FIG. 5 is a side sectional view of an alternative embodiment of a compact optical module having a single light source that is a LED.

FIG. 6 is a sectional perspective view of an alternative embodiment of a compact optical module having a single light source that is a LED.

FIG. 7 is a sectional view of an alternative embodiment of a compact optical module having a plurality of light sources that are LEDs.

FIG. 8 is a close up view of an LED light source and wire connections of an alternative embodiment of a compact optical module.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

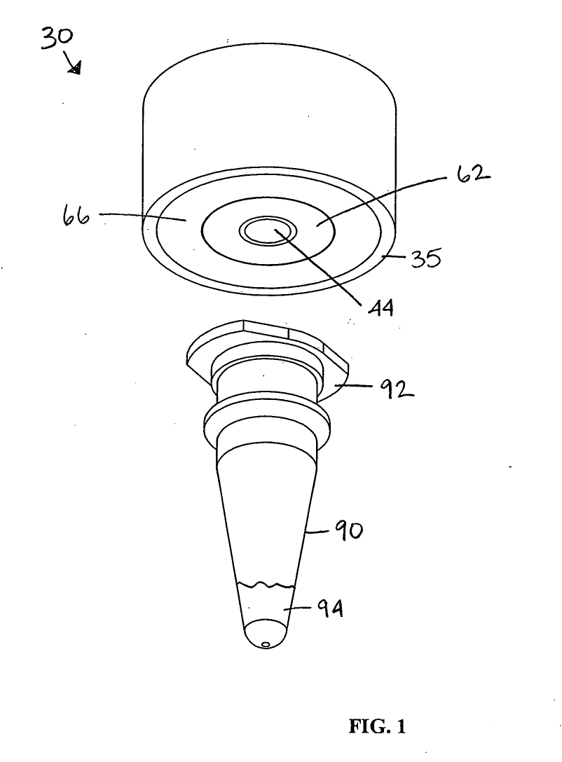

A compact optical module for fluorescence excitation and detection is shown generally at 30 in FIG. 1. The compact optical module has one optical light path for the illumination (excitation), and a different optical light path for the detection of fluorescence. The compact optical module uses apertures for directing and shaping the light.

A plurality of light sources is located around a detection aperture to shine excitation light onto a sample. Careful aperturing of the light sources around the central detection aperture allows for a compact design that illuminates the sample and minimizes the amount of scattered light. Once illuminated with light of the appropriate wavelength, the sample emits fluorescent light that is detected by a detector above the detection aperture. The emitted fluorescent light travels through the detection aperture, to an emission filter, and to the detector. Having the emitted light travel directly to the detector obviates the need for a beam splitter, lens, or any other optics, thereby reducing the cost and complexity of the design, eliminating losses from the eliminated optics, and reducing the size of the design. A fluorescence detection system using the compact optical module is compact, and the detected light has both high quality (small amount of scattered light) and quantity (no losses from beam splitters).

When the system is applied to qPCR, the PCR amplification scheme used is not critical, but generally qPCR requires the use of either a nucleic acid polymerase with exonuclease activity or a population of double stranded DNA that increases during the course of the reaction being monitored. Thermal cyclers used in qPCR are typically programmable heating blocks that control and maintain the temperature of the sample through the temperature-dependent stages that constitute the cycles of PCR: template denaturation, primer annealing, and primer extension. These temperatures are cycled up to forty times or more to obtain amplification of the DNA target. Thermal cyclers use different technologies to effect temperature change including, but not limited to, peltier heating and cooling, resistance heating, and passive air or water heating.

As used herein, “optical module” refers to the optics of systems for thermal cycling known in the art including, but not limited to, modular optics, non-modular optics, and any other suitable optics. The optical module can be used for characterizing a plurality of samples of biological material after thermal cycling of DNA to accomplish a polymerase chain reaction (PCR), during thermal cycling of DNA to accomplish a quantitative polymerase chain reaction (qPCR), after thermal cycling of DNA after a reverse transcriptase reaction to accomplish a reverse transcription-polymerase chain reaction (RT-PCR), during thermal cycling of DNA after a reverse transcriptase reaction to accomplish a reverse transcription-quantitative polymerase chain reaction (RT-qPCR), immuno-polymerase chain reaction (I-PCR), or for fluorescence detection during other nucleic acid amplification types of experiments. The optical module controls the illumination light and the detection of fluorescence.

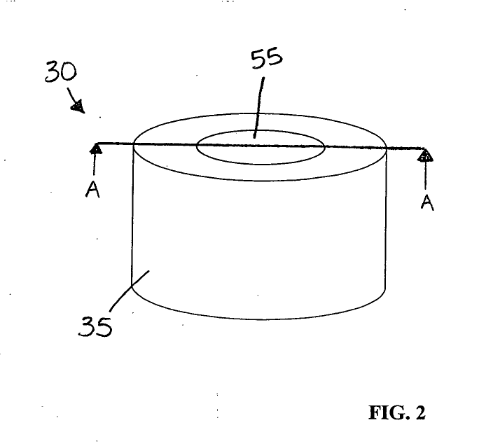

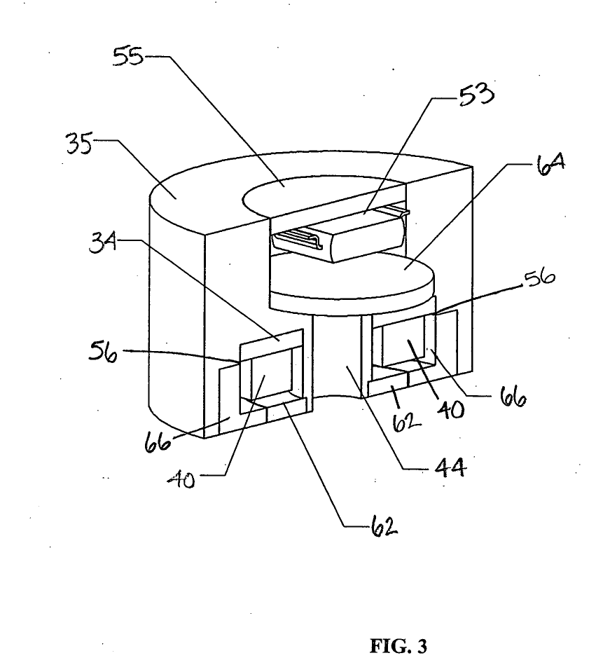

FIGS. 1-3 show various views of an embodiment of the compact optical module 30. FIG. 1 shows a bottom perspective view of the compact optical module 30. FIG. 2 shows a top perspective view of the compact optical module 30. FIG. 3 shows a sectional perspective view of the compact optical module 30 taken along line A-A in FIG. 2. The compact optical module 30 has a detection aperture 44 and a plurality of light sources 40 located around the detection aperture 44 inside a housing 35. The optical module 30 is used for detecting fluorescence from a plurality of samples 94 in a plurality of sample tubes 90. The illumination path of the optical module 30 includes an excitation filter 62 and an illumination baffling 66. As best shown in FIG. 3, the excitation filter 62 is located below the plurality of light sources 40. The illumination baffling 66 is located adjacent to and below the plurality of light sources. The detection path of the optical module 30 includes the detection aperture 44, an emission filter 64, and a detector 53. The optical module 30 illuminates from the outside, directing excitation light to the samples from around the central detection aperture 44, and collects fluorescence from the inside through the detection aperture 44. A plurality of leads extend from the detector 53 and the plurality of light sources 40 to connect the detector 53 plurality of light sources 40 to electronics. The electronics both power the light sources 40 and detect the signal from the detector 53. The electronics may be remotely attached to the optical module 30. The electronics may be under computer control. The optical module 30 may be a single component or composed of a plurality of assembled parts.

The optical module 30 is compact, being comparable in size to the sample holders that hold the samples that the optical module 30 measures. Use of the same optical module 30 for all samples reduces measurement variability from different samples compared to using different optics or different optical paths through the same optics for different samples, including optics that illuminate and detect from multiple samples simultaneously. FIG. 1 shows the excitation filter 62 is ring-shaped and covers the plurality of light sources 40 located along the periphery. In an embodiment, the centrally located detection aperture 44 and the detector 53 are surrounded by four banks of light sources 40. As shown in FIG. 3, the emission filter 64 is located between the detector 53 and the samples. The plurality of light sources 40 is offset slightly further from the optical axis than the excitation filter 64 to direct the light towards the samples.

The detection aperture 44 is centered on the optical axis of the optical module 30. The detector 53 is located at an end of the detection aperture 44. Adjacent to the detector 53 are mounting boards 34 for the plurality of light sources 40. The ring covering portions of the plurality of light sources 40 is the illumination baffling 66. The excitation filter is supported by the housing 35 and the illumination baffling 66.

As shown in FIG. 2 and FIG. 3, the housing 35 supports a mounting board 55 for the detector 53. The detector 53 is contained in a cavity 56 that also contains the emission filter 64. The emission filter 64 is located adjacent to the end of the detection aperture 44 through which light emitted from the sample travels. Outside and adjacent to the detection aperture 44 are a plurality of light source cavities that house the mounting boards 34 for the plurality of light sources 40. The excitation filter 62 and the illumination baffling 66 are adjacent to the light sources 44. Illumination from the plurality of light sources 40 passes through the excitation filter 62 and on towards the sample.

The detector 53 can be mounted to the mounting board 55 through a variety of methods. If the detector 53 is fabricated as an unpackaged silicon die, the detector can be die attached to mounting board 55 using die mounting glue known in the semiconductor fabrication industry and the electrical connections can be wire bonded to the respective pads on both the detector die 53 and the mounting board 55. If the detector 53 is fabricated as a surface mount technology (SMT) package, the detector can be soldered to the mounting board 55 using solder paste and a reflow oven known in the SMT fabrication industry. The solder then forms the basis for the physical connection and the electrical connection. If the detector 53 is fabricated as a through hole (TH) package, the detector can be soldered to the mounting board 55 by inserting the through hole leads of the detector 53 into the corresponding holes in the mounting board 55 and wave soldering the connection. The solder then forms the basis for the physical connection and the electrical connection. The detector 53 can be mounted to the mounting board 55 using variations on these techniques or other techniques known to those skilled in the art of electronic assembly and be within the spirit and scope of the disclosed embodiments.

The illumination baffling 66 is used to block unwanted illumination radiation from scattering throughout the optical system. Unwanted illumination radiation is radiation that does not illuminate the sample. Unwanted illumination radiation reduces the sensitivity of the system by adding to the background and noise without concomitantly increasing the signal. The illumination baffling helps prevent unwanted illumination from reaching the detector 53 by blocking unwanted illumination before it escapes the optical module 30.

An excitation light is produced by the plurality of light sources 40 mounted to the mounting boards 34. A plurality of excitation light rays is emitted from the light sources 40 toward the samples. In FIG. 1, the excitation light from the light source 40 travels toward the samples. The light from the light source 40 travels through the excitation filter 62, and then toward the sample tube 90. The light is directed toward the inside of the sample tube 90, but aiming the light from the light source 40 onto a cap 92 of the sample tube 90 is effective. Using free space optics for the illumination tube instead of fiber optics enables a more compact design because optics for coupling the excitation light into the fiber optics and optics for collimating the excitation light before it reaches the excitation filter are not required.

The light travels through the cap 92 and into the sample tube 90 where it excites fluorogenic probes typically used in PCR that are within the sample 94 in the sample tube 90, causing the sample 94 to fluoresce. Fluorogenic probes can be placed in each sample tube so that the amount of fluorescent light emitted as DNA strands in the samples that replicate during each thermal cycle is related to the amount of DNA in the sample.

Emitted fluorescent light from the sample 94 passes through the cap 92, and is collected by the detection aperture 44. The fluorescent light travels through the detection aperture 44 and passes through the emission filter 64, which preferentially transmits signal light and blocks scattered light collected by the detection aperture 44. After being transmitted by the emission filter 64, the light travels onto the detector 53. The detector 53 converts the intensity of the light into a voltage that is a function of the light intensity. The sense and control electrics for the detector 53 are connected to the detector 53 by leads. By detecting the amount of emitted fluorescent light, the detection system measures the amount of DNA that has been produced. Data can be collected from each sample tube 90 and analyzed by a computer.

The light source 40 supplies the excitation light that passes through the excitation filter 62, which selects the wavelength of light to excite the sample. The excitation light continues toward the plurality of samples.

Some of the light transmitted by the cap 92 of the sample tube 90 is absorbed by the sample 94 and excites the fluorogenic probes within the sample, re-emitting light through fluorescence. The re-emitted light (fluorescence) that travels up the sample tube 90, exits through the cap 92, and falls within the detection aperture 44. The light travels through the detection aperture 44 to the emission filter 64 and onto the detector 53.

In an embodiment, the plurality of light sources 40 partially surrounds the detection aperture 44. The plurality of light sources 40 may be located at distinct positions around the detection aperture 44 to maximize the light reaching the sample and the collection of emitted light. In this embodiment, the plurality of light sources 40 does not completely surround the detection aperture 44, and gaps may exist between adjacent light sources. For example, light sources may be located every 90 degrees around the detection aperture 44, every 45 degrees around the detection aperture 44, or continuously except for one gap. The spacing between adjacent light sources may be uniform, varied, or random. Those skilled in the art will recognize that any number of light sources and any type of spacing between adjacent light sources is within the spirit and scope of the disclosed embodiments.

The light source 40 is mounted to the underside of the mounting board 34. The mounting board 34 may be a circuit board. The light source 40 may be broad band or narrow band, and it must be bright enough for the optical module 30 to be able to detect the concentration of probes used in the reaction, for example, qPCR.

A light emitting diode (LED) or a plurality of LEDs are particularly suited as the light source 40 because LEDs stabilize quickly, are compact, and are available at various wavelengths. An LED is a semiconductor device that emits light through electroluminescence. An LED is a special type of semiconductor diode. Like a normal diode, an LED consists of a chip of semiconducting material impregnated, or doped, with impurities to create a structure called a pn junction. Charge-carriers (electrons and holes) are created by an electric current passing through the junction. When an electron meets a hole, it falls into a lower energy level, and releases energy in the form of light.

LEDs emit incoherent quasi-monochromatic light when electrically biased in the forward direction. The color of light emitted depends on the semiconducting material used and can be near-ultraviolet, visible, or infrared. The wavelength of the light emitted, and therefore its color, depends on the bandgap energy of the materials forming the pn junction. A normal diode, typically made of silicon or germanium, emits invisible far-infrared light, but the materials used for an LED have bandgap energies corresponding to near-infrared, visible, or near-ultraviolet light.

A laser diode or a plurality of laser diodes are also suited as the light source 40 because laser diodes also stabilize quickly, are compact, and are available at various wavelengths. Laser diodes are also more directional and spectrally pure than LEDs. A laser diode generally refers to the combination of the semiconductor chip that does the actual lasing along with a monitor photodiode chip (used for feedback control of power output) housed in a package. Diode lasers use nearly microscopic chips of Gallium-Arsenide or other exotic semiconductors to generate coherent light in a very small package. The energy level differences between the conduction and valence band electrons in these semiconductors provide the mechanism for laser action. Laser diodes have desirable characteristics such as compactness (the active element is about the size of a grain of sand), low power and voltage requirements, high efficiency (especially compared to gas lasers), high reliability, and long lifetimes with proper treatment.

Unlike LEDs, laser diodes require much greater care in their drive electronics or else they cease operation instantly. There is a maximum current that must not be exceeded for even a microsecond, which depends on the particular device as well as junction temperature.

The light source 40 may be pulsed as disclosed in Assignee's co-pending application Ser. No. 60/677,747, filed May 4, 2005, the disclosure of which is hereby incorporated herein by reference in its entirety.

The optical design should take into account the positions and sizes of the light source 40, the detection aperture 44, and the sample tubes. For example, more light can be coupled into the sample tube with a wider diameter detection aperture 44, but a wider diameter detection aperture 44 means the plurality of light sources 40 are farther from the central axis of the sample tubes, which may result in more scattering of illumination light and less illumination light reaching the sample 94. In addition, the excitation filter 62 performs best when light incident on it is collimated.

The optical module 30 optimizes the size of the photodiode through attention to the tradeoff between improved detection (from a bigger photodiode) and reduced illumination (because the light source is further away from the central axis of the sample tubes).

The optical module 30 optimizes the optics through alignment of the light source 40 to maximize the ratio of light reaching the sample to background scattered light, reduction of light scattered internally in the module, and reduction of the area from which scattered light can reach the detector 53 without compromising the ability of fluorescence from the sample to reach the detector 53. Methods to achieve this optimization include incorporating a light-tight baffle between the detector 53 and the light source 40, angling the light source 40 relative to the tube central axis, and aperturing the light source 40 and the detector.

The optical module 30 may include apertures and baffles for control and reduction of scattered light because scattered light can reduce the sensitivity of the optical module 30. The filters 62, 64 perform best with normally incident light and lose efficiency as the incident angle increases, particularly to greater than 20 degrees. Aperturing along the paths before the filters 62, 64 prevents light of too great an angle reaching the filters 62, 64. Because the filters block light of unwanted wavelength most effectively when that light is normally incident on the filters, using apertures and baffles to eliminate this light can improve the sensitivity of the module. For the filters 62, 64 to select the correct wavelength of light for detection, the light should be parallel or at least not diverging by more than about a 20° half-angle upon entering the filters 62 and 64.

If used, the filters 62, 64 are preferably narrow band-pass filters that attenuate frequencies above and below a particular band. The filters are preferably a matched pair of filters, consisting of the excitation filter 62 and the emission filter 64. The excitation filter 62 transmits light that excites a particular fluorogenic probe of interest and effectively blocks light that excites other probes or is the same or nearly the same wavelength as the fluorescence emitted by the fluorogenic probes. The emission filter 64 transmits light from the same, excited fluorgenic probe efficiently, but blocks light from other probes and the excitation light effectively. The specifications of the filters depend on the light source. For example, because an incandescent source has a broader spectrum than an LED source, the filters used with an incandescent source need to attenuate a larger range of wavelengths than the filters used with an LED source.

After the light passes through the emission filter 64, the light selected by the filter continues on to the detector 53. Because the ratio of signal light to background light is determined primarily by the pair of filters 62, 64, once the light emitted by the sample is transmitted by the emission filter 64, as much of it as possible should be detected by the detector 53. Because the distance between the emission filter 64 the detector 53 is small, sufficient light reaches the detector 53 and only a small amount of light does not reach the detector 53. In an embodiment, a lens or other condensing optics may be used to maximize the light reaching the detector 53, without regard for image quality.

The detector 53 is capable of determining the fluorescence from the fluorogenic probes in the sample by converting that fluorescence to a voltage. The detector 53 preferably comprises a photodiode for detecting the fluorescent light. Photodiodes tend to be the smallest and least expensive detection methods. A photodiode detector may be a silicon diode that is photo sensitive. Over a wide range, the amount of light directed into the photodiode detector is directly proportional to the current that the photodiode detector emits. Electronics attached to the photodiode can convert the current to a voltage for input into an analog digital converter, which converts the signal from the detector into a number that can be human or computer readable.

With careful design of the light source, optics, and electronics, photodiodes may be used in the optical module 30. The optical module 30 minimizes the electronics noise though circuit design, cable routing and shielding, using a large electronics gain for the signal from the photodiode, choosing the highest power LEDs available that meet the size constraints of the optical module 30, and optical design that directs as much light as possible to the sample and collects as much light as possible from the sample while simultaneously minimizing the scattered light that is unrelated to the sample.

In other embodiments, other detectors known in the art could be used including, but not limited to, an avalanche photodiode (APD), a photomultiplier tube (PMT), a charge-coupled device (CCD), or similar photodetectors. Avalanche photodiodes typically have faster responses to signals than photodiodes, but require higher voltages to operate and are more expensive. Photomultiplier tubes are typically the most sensitive and the most expensive, and photomultiplier tubes require the highest voltage power supplies. Charge-coupled devices have sensitivity comparable to photodiodes, they provide spatial resolution to the detected light, and they are more expensive than photodiodes.

The electronics of the optical module 30 should be optimized so that its contribution to the noise that limits the sensitivity of the module is as low as possible. Design guidelines that help reach this goal include locating a preamplifier as close as possible to the detector, shielding the optical module from electromagnetic interference, increasing the total electronics gain, and RC filtering the signal.

Optimization of the electronics should occur in concert with optimization of the light source. The light source should produce as stable an illumination as possible.

Once the electronics and light source generate as little noise as possible, the intensity of the light source should be optimized. At low light levels, the detection and electronics noise limits the sensitivity. This noise is independent of light intensity, and because the signal from the optical module 30 increases with increasing light intensity, increasing the light intensity will increase the sensitivity of the optical module 30. At some light intensity level, however, the optical noise (inherent in the generation and detection of the light) will become larger than the electronics noise, and once that intensity is reached, more light intensity will not increase the sensitivity of the optical module 30. The light intensity should be raised as high as possible until the sensitivity of the module no longer increases. Limitations on how high the light intensity can be raised are set by the physical properties of the light source and the space available, as higher power light sources are bigger, require more volume for heat dissipation, and require larger power supplies. Although theoretical modeling helps understand the noise and signal sources, the optimum light intensity is most often determined empirically.

The optical module 30 has the plurality of light sources 40 completely or partially around the detection aperture 44. The plurality of light sources 40 surround the detection aperture 44 which is located in the center of the plurality of light sources 40. The plurality of light sources 40 are located continuously or discretely around the detection aperture 44 to illuminate the samples. The detection aperture 44 collects the fluorescence and directs the signal to the detector 53.

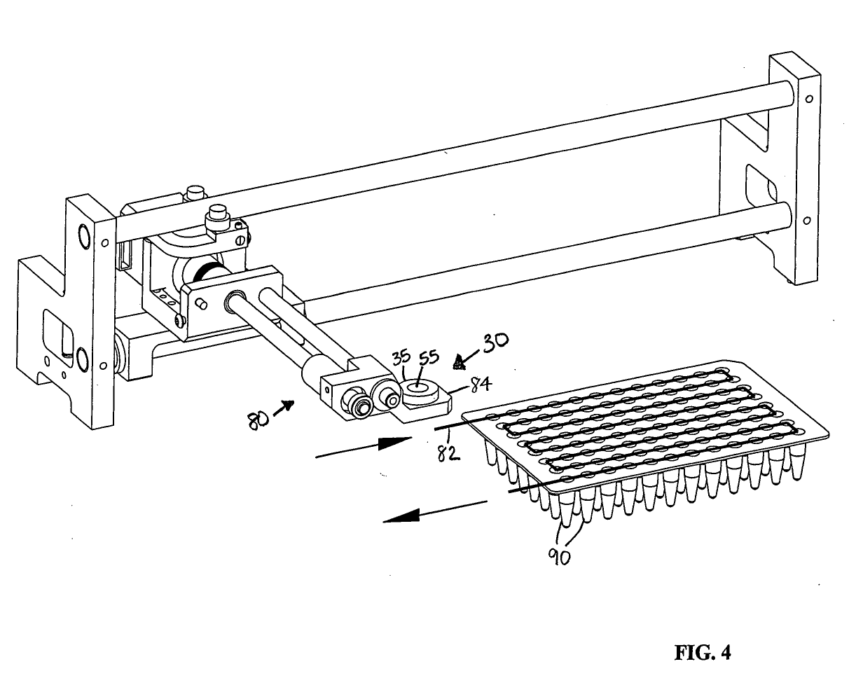

As shown in FIG. 4, the optical module 30 can be used for scanning over the samples of a 96 well (8×12 array) thermal cycler that allows optical access to the samples. The optical module 30 is held to the scanning mechanism by a mounting bracket 84. The optical module should remain fixed in the mounting bracket 84. Those skilled in the art will recognize that the optical module can be held to the scanning mechanism by other mounting methods known in the art and be within the spirit and scope of the presently disclosed embodiments.

FIG. 4 shows a serpentine method for scanning an optical module over an array of samples. The optical module 30 is shown attached to a two-axis motion system 80 that can be controlled by a computer. A path 82 traversed by the optical module 30 can be defined by blind stepping (driving the axes for predefined time periods). Alternatively, the path 82 can be defined through feedback from a sensor or sensors (not shown). Such sensors could be, for example, scales used for measuring the absolute position of the optical module 30 or limit switches set to sense when the optical module 30 is over or at the end of a particular row or column. The path 82 is serpentine and takes the optical module 30 along each row of samples, starting to the left of the left-most sample of a row and ending to the right of the right-most sample of every other row. The motion system 80 then moves the optical module 30 to the next row before scanning the optical module 30 in the opposite direction as the previous row. Although FIG. 4 shows the optical module path over a 96 well thermal cycler, those skilled in the art will recognize that 48 well, 384 well, 1536 well, and other multiple well thermal cyclers are within the spirit and scope of the disclosed embodiments.

In an embodiment, multiple optical modules 30 are packaged together in single unit to scan samples for multiplexing (detection of different fluorogenic probes from the same sample). Each optical module 30 can represent a separate optics channel for a different fluorophore. As the unit with multiple optical modules 30 moves across a plurality of samples, each individual optical module 30 scans the samples sequentially, producing several readings. The multiple optical modules 30 can be connected to a two-axis motion system (shown in FIG. 4) to move across a two-dimensional array of samples. Two, three, four, five, or more optical modules 30 can be packaged together as single unit to interrogate the individual samples. The multiple optical modules can be arranged in straight line one behind each other, in a square, in a parallelogram, in a diamond or other patterns and be within the spirit and scope of the disclosed embodiments.

In an embodiment, the locations of the light sources 40 and the detector 53 can be switched so fluorescence from the sample is collected along the periphery toward the outside of the optical module 30, and the excitation light reaches the sample from the center the optical module 30. In this embodiment, the excitation light is directed to the sample from the inside (along the optical axis), and the fluorescent light emitted from the sample is detected on the outside. The embodiment with the light sources 40 located on the optical axis might reduce the unwanted illumination scattered into the detectors and increase the illumination of the sample because the optical path from the light sources 40 to the sample 94 is more direct.

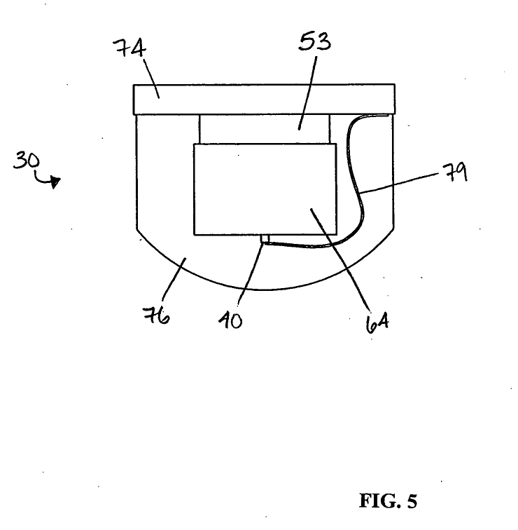

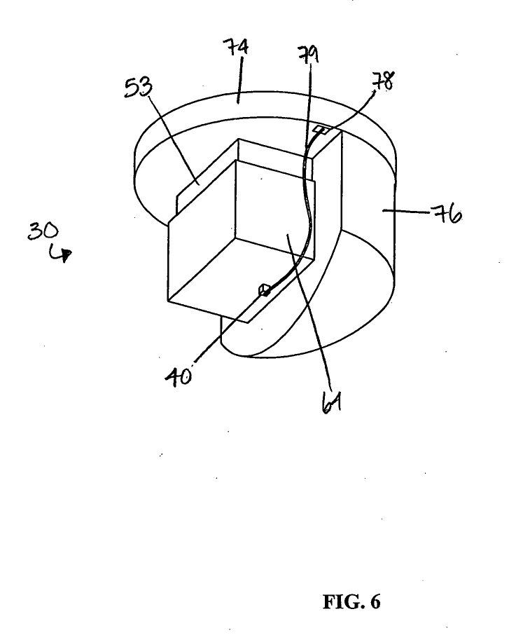

FIG. 5 shows a sectional side view of an alternative embodiment of a compact optical module having a single light source that is an LED. FIG. 6 shows a sectional perspective view of an alternative embodiment of a compact optical module having a single light source that is a LED. The compact optical module 30 includes the LED light source 40, the photodiode detector 53, the emission filter 64, a substrate base 74, and a substrate cover 76. The detector 53 is mounted on the substrate base 74. The emission filter 64 is adjacent to the detector 53. A single light source 40, an LED die, engages the emission filter 64. The LED die 40 may mount on the emission filter 64. The LED directly illuminates the sample and because the surface area of the LED is small in comparison with the surface area of the detector 53, the LED does not block much of the light that the sample emits back to the detector 53. In operation, the LED die illuminates the sample and light emitted by the sample travels through the emission filter 64 to the detector 53. The embodiment having a single light source that is an LED allows for the smallest and lightest compact optical module 30.

The detector 53 is mounted to the substrate base 74 and wires 79 are bonded to pads 78 printed on the substrate base 75, similar to the way the pads on a circuit board are printed. The LED die is bonded to the emission filter 64 and has wires 79 running from the LED die bonded to pads 78 on the substrate base 74 to form the electrical connection to the power supply connected to the substrate base 74.

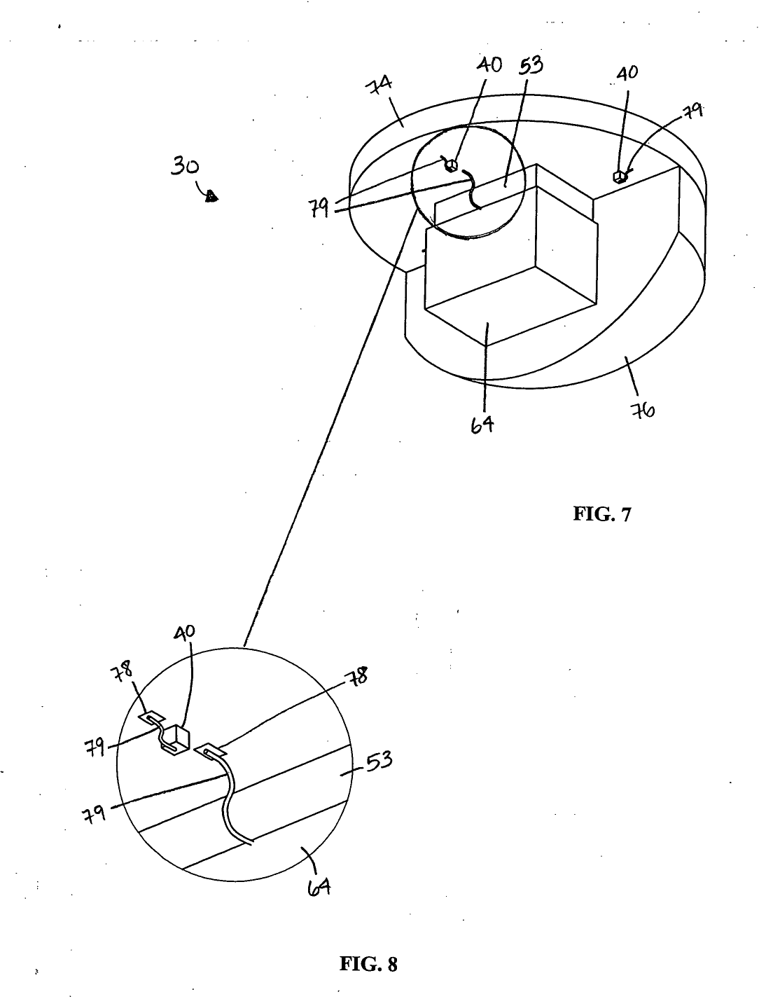

FIG. 7 is a sectional view of an alternative embodiment of a compact optical module having a plurality of light sources that are LEDs. The compact optical module 30 includes a plurality of LED light sources 40, the photodiode detector 53, the emission filter 64, the substrate base 74, and the substrate cover 76. FIG. 8 is a close up view of an LED light source and wire connections of an alternative embodiment of a compact optical module. The LED light sources are mounted to the substrate base 74 to not obscure the light emitted from the sample that heads to the emission filter 64.

When the LED is used as the light source 40, the LED may be a raw, unpackaged LED or a packaged LED. The LED light source 40 can be an unpackaged LED semiconductor die. The LED die can be square with dimensions of about 0.013 inches on a side or have larger or smaller dimensions. Those skilled in the art will recognize that the LED could have a rectangular shape, a circular shape, oblong shape or other shapes and be within the spirit and scope of the presently disclosed embodiments. The LED is die-attached to the emission filter 64 through the use of semiconductor glue or other attachment methods known to those skilled in the art of semiconductor assembly.

Manufacture of a packaged integrated circuit typically involves a small silicon die that is attached (glued) on to a larger substrate with small wires bonded to the die to make the electrical connection. The integrated circuit is then encapsulated in a substrate cover, and a substrate base is placed on that package that are attached to the wires. The packaged integrated circuit then can be handled and placed on circuit boards and connected to electrical devices.

The photodiode detector 53 is an unpackaged photodiode semiconductor die. The photodiode detector can be square with dimensions of about 0.217 inches on a side or have larger or smaller dimensions. Those skilled in the art will recognize that the photodiode detector could have a rectangular shape, a circular shape, oblong shape or other shapes and be within the spirit and scope of the presently disclosed embodiments. The photodiode detector 53 is die-attached to the substrate base 74 through the use of semiconductor glue or other attachment methods known to those skilled in the art of semiconductor assembly.

The substrate base 74 may be a circuit board or a mounting board. The substrate base 74 should be thin and flat and suitable for die-attaching components and wire bonding. The substrate base may be composed of standard printed circuit board (PCB) materials, including but not limited to, fiberglass, polymer/glass fibre cloth laminate, laminates made from woven glass fiber material impregnated with epoxy resin, Flame Retardant 4 (FR4), and other similar materials known to those skilled in the art. The substrate base 74 may be composed of ceramics including alumina, beryllia, and aluminum nitride, plastics, or other materials known to those skilled in the art.

The assembly is protectively encapsulated in the substrate cover 76. The substrate cover 76 is a non-electrically conductive encapsulant material which is formed or molded over the electronic components. The substrate cover 76 supports the detector 53, the light sources 40, and the emission filter 64. The substrate cover 76 permits the passage of light. The substrate cover can act as a lens to focus the light. The substrate cover 76 may be composed of epoxy, glass, plastic, or other materials known to those skilled in the art.

FIG. 8 is a close up view of an LED light source and wire connections of an alternative embodiment of a compact optical module. Electrical connections are made between the photodiode detector 53, LED light source 40, and the substrate base through wire bonding familiar to those skilled in the art of semiconductor assembly. The wires 79 are bonded to pads 78 on the substrate base 74 to form the electrical connection to the power supply connected to the substrate base 74.

When LEDs are used as the light source, the excitation light that is emitted by the LED light source 40 should be effectively blocked by the emission filter 64 so that unwanted excitation light is not detected by the photodiode detector 53. But if the particular application has sensitivity requirements that require further excitation light blocking than provided by the emission filter 64, a small opaque light baffle can be inserted between the LED light source 40 and the emission filter 64 blocking direct transmission of light from the LED light source 40 to the photodiode detector 53.

This unique package configuration opens up many optical configurations never before possible. The compact optical module can easily be brought close to samples for use in a scanning system. The compact optical module can be used in a microfluidics application where the size of the optical system is important. The compact optical module being encapsulated into a tiny package makes it environmentally robust allowing for use in applications where shock, vibration, or humidity make use traditional optical systems difficult or problematic.

The compact optical module can be used with qPCR instruments of various makes and models, and is not limited to use in an optical module as exemplified in FIGS. 1-8. Other qPCR instruments, systems, and methods of detecting the fluorescence from a qPCR reaction could also benefit from a compact optical module. For example, the compact optical module could be used with the apparatus for thermally cycling samples of biological material described in assignee's U.S. Pat. No. 6,657,169, and the entirety of this patent is hereby incorporated herein by reference. The compact optical module could also be used with the Mx3000P Real-Time PCR System and the Mx4000 Multiplex Quantitative PCR System (commercially available from Stratagene California in La Jolla, Calif.) using a tungsten halogen bulb that sequentially probes each sample, detecting fluorescence with a photomultiplier tube. In addition, the compact optical module could be used with qPCR instruments incorporating any or all of the following: a tungsten halogen bulb that sequentially probes each sample; a scanning optical module; stationary samples, light sources, and detectors; stationary LEDs and a detector to probe spinning samples sequentially; and other qPCR instruments known in the art.

The samples of biological material are typically contained in a plurality of sample tubes. The sample tubes are available in three common forms: single tubes; strips of eight tubes attached to one another; and tube trays with 96 attached sample tubes. The optical module 30 is preferably designed to be compatible with any of these three designs.

Each sample tube may also have a corresponding cap for maintaining the biological reaction mixture in the sample tube. The caps are typically inserted inside the top cylindrical surface of the sample tube. The caps are relatively clear so that light can be transmitted through the cap. Similar to the sample tubes, the caps are typically made of molded polypropylene; however, other suitable materials are acceptable. Each cap has a thin, flat, optical window on the top surface of the cap. The optical window in each cap allows radiation such as excitation light to be transmitted to the fluorogenic probes in the samples and emitted fluorescent light from the fluorogenic probes in the samples to be transmitted back to an optical detection system during cycling.

Other sample holding structures such as slides, partitions, beads, channels, reaction chambers, vessels, surfaces, or any other suitable device for holding a sample can be used with the disclosed embodiments. The samples to be placed in the sample holding structure are not limited to biological reaction mixtures. Samples could include any type of cells, tissues, microorganisms, or non-biological materials.

The compact optical module can be used for detecting fluorescence in other biological applications including, but not limited to, green fluorescent protein, DNA microarray chips, protein microarray chips, flow cytometry, and similar reactions known to those skilled in the art.

All patents, patent applications, and published references cited herein are hereby incorporated by reference in their entirety. It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. An apparatus for detecting fluorescence comprising:
a substrate base;
a detector adjacent to the substrate base for determining the amount of fluorescence;
an emission filter adjacent to the detector;
a light source for emitting an excitation light, the light source engaging the emission filter; and
a cover formed over the detector, the emission filter, and the light source.

2. The apparatus of claim 1 wherein the light source is an unpackaged light emitting diode.

3. The apparatus of claim 1 wherein the light source is a packaged light emitting diode.

4. The apparatus of claim 1 wherein the light source is a laser diode.

5. The apparatus of claim 1 further comprising a plurality of light sources that are light emitting diodes.

6. The apparatus of claim 1 further comprising electrical connections between the light source and the substrate base.

7. The apparatus of claim 1 further comprising electrical connections between the detector and the substrate base.

8. The apparatus of claim 1 wherein the detector is a photodiode.

9. The apparatus of claim 1 wherein the detector is an avalanche photodiode.

10. The apparatus of claim 1 wherein the detector is a charge-coupled device.

11. The apparatus of claim 1 wherein the substrate base is a printed circuit board having pads.

12. The apparatus of claim 1 wherein the cover is a non-conductive encapsulant material.

13. A detection system for detecting fluorescence from a plurality of samples comprising:
a detection aperture for receiving fluorescent light;
a plurality of light emitting diodes for emitting an excitation light, the plurality of light emitting diodes located around the detection aperture; and
a detector adjacent to the detection aperture for determining the amount of fluorescence.

14. The system of claim 13 further comprising an excitation filter adjacent to the plurality of light emitting diodes.

15. The system of claim 13 further comprising an illumination baffling adjacent to the plurality of light emitting diodes.

16. The system of claim 13 further comprising an emission filter adjacent to the detector.

17. The system of claim 13 wherein the detection aperture is a hollow tube.

18. The system of claim 13 wherein the plurality of light emitting diodes are located outside the detection aperture.

19. The apparatus of claim 13 wherein the detector is a photodiode.

20. The apparatus of claim 13 wherein the detector is an avalanche photodiode.

21. The apparatus of claim 13 wherein the detector is a charge-coupled device.

22. A method for detecting fluorescence comprising:
emitting an excitation light from a plurality of light sources located around a detection aperture;
directing the excitation light to an excitation filter;
illuminating a sample with the excitation light to generate an emission light; and
detecting the optical characteristics of the emission light using a detector located at the end of the detection aperture.

23. The method of claim 22 wherein the plurality of light sources are light emitting diodes.

24. The method of claim 22 wherein the plurality of light sources are laser diodes.

25. The method of claim 22 wherein the plurality of light sources are located outside the detection aperture.

26. The method of claim 22 wherein the detector is a photodiode.
